(19) United States
(12) Patent Application Publication
(10) Pub. No.: US 2026/0088739 A1
(43) Pub. Date: Mar. 26, 2026

(54) SHUNTLESS MOTOR CONTROL

(71) Applicant: Infineon Technologies AG, Neubiberg (DE)

(72) Inventors: Thorsten BUCKSCH, München (DE); Benno KÖPPL, Markt Indersdorf (DE); Jaafar MEJRI, Ottobrunn (DE)

(21) Appl. No.: 18/896,283

(22) Filed: Sep. 25, 2024

(51) Int. Cl. H02P 6/08; G01R 19/25; H02P 29/68

(52) U.S. Cl. CPC H02P 6/085; G01R 19/2506; H02P 29/68

(57) ABSTRACT

A controller operates a bridge circuit in a freewheeling phase in which a freewheeling current flows through a body diode of a power transistor of the bridge circuit. The controller performs a first measurement during the freewheeling phase to determine a junction temperature of the power transistor. The controller performs a second measurement during the freewheeling phase to determine a drain voltage of the power transistor.

### TECHNICAL FIELD OF THE INVENTION

This disclosure relates to motor control and more specifically, techniques for measuring current through a motor without using a shunt resistor.

### BACKGROUND

Power transistors are used in a wide variety of applications in order to control power being delivered to a load, such as a motor. As examples, a power transistor may comprise a Field Effect Transistor (FET), an insulated gate bipolar transistor (IGBT), a bipolar junction transistor (BJT), or another type of power transistor. Examples of FETs may include, but are not limited to, junction field-effect transistor (JFET), metal-oxide-semiconductor FET (MOSFET), dual-gate MOSFET, insulated-gate bipolar transistor (IGBT), any other type of FET, or any combination of the same. Examples of MOSFETS may include, but are not limited to, PMOS, NMOS, DMOS, or any other type of MOSFET, or any combination of the same. MOSFETs may be formed in silicon, gallium nitride, silicon carbide, or other materials.

Power transistors are typically controlled by a driver circuit via a pulse modulation (PM) signals. PM signals generally refer to pulse width modulation (PWM) signals, pulse frequency modulation (PFM) signals, pulse duration modulation signals, pulse density modulation signals, or another type of modulated control signal used to control a power switch. PM control signals may be generated by a processor and communicated to a driver circuit. The driver circuit may amplify the PM control signals to generate PM drive signals, which can be applied to the gate of a power transistor so as to control on/off switching of the power switch, and thereby control the average amount of power delivered through the power switch to a load. The on/off switching of the power transistor effectively chops its power delivery up into discrete parts. The average value of voltage and/or current fed to a load can be controlled by turning the power transistor ON and OFF at a fast rate. The longer the switch is on compared to the off periods, the higher the total power supplied to the load.

In many applications, different power transistors are configured in a high-side and low-side configuration, and the ON-OFF switching of the power transistors is synchronized in order to deliver the desired power to a switch node positioned between the high-side and low-side switch. Three-phase inverter circuits, for example, may comprise three different half bridge circuits, which each include a high-side and a low-side power switch, for controlling three different phase currents for a multi-phase electric motor.

It is often desirable or necessary to monitor current through a motor, e.g., as part of a regulation loop for controlling the motor. For such current monitoring, a shunt resistor is typically used. Shunt resistors for measuring current are relatively expensive components, and the use of shunt resistors for current measuring purposes in motor control can create challenges and limitations for layout of other circuit components.

### SUMMARY

In some aspects, a method is described. The method includes operating a bridge circuit in a freewheeling phase in which a freewheeling current flows through a body diode of a power transistor of the bridge circuit. The method includes performing a first measurement during the freewheeling phase to determine a junction temperature of the power transistor. The method includes performing a second measurement during the freewheeling phase to determine a drain voltage of the power transistor.

In some aspects, a controller is described. The controller is configured to control a bridge circuit in a freewheeling phase in which a freewheeling current flows through a body diode of a power transistor of the bridge circuit. The controller is configured to perform a first measurement during the freewheeling phase to determine a junction temperature of the power transistor. The controller is configured to perform a second measurement during the freewheeling phase to determine a drain voltage of the power transistor.

In some aspects, a system is described. The system includes a motor, a bridge circuit that is controllable to supply energy to the motor, and a controller. The controller is configured to operate a bridge circuit in a freewheeling phase in which a freewheeling current flows through a body diode of a power transistor of the bridge circuit. The controller is configured to perform a first measurement during the freewheeling phase to determine a junction temperature of the power transistor. The controller is configured to perform a second measurement during the freewheeling phase to determine a drain voltage of the power transistor.

### BRIEF DESCRIPTION OF THE DRAWINGS

FIG. 1 is a block diagram of a system configured to control a motor according to some embodiments.

FIG. 2 is a circuit diagram that depicts a bridge circuit according to some embodiments.

FIG. 3 is a timing diagram that depicts operation of a controller to control a bridge circuit to supply energy to a motor and measure a load current according to some embodiments.

FIGS. 4A-4C are circuit diagrams that depict operation of a bridge circuit in respective phases of a low side switching cycle of the bridge circuit.

FIGS. 5A-5C are circuit diagrams that shows operation of a bridge circuit in respective phases of a high side switching cycle of the bridge circuit.

FIG. 6 is a circuit diagram showing one example of a three phase bridge circuit that may be operated to determine a load current associated with at least one phase of the bridge circuit according to some embodiments.

FIG. 7 is a graph showing of three different waveforms of current associated with three phases of a three-phase electric motor.

FIG. 8 is a flow diagram that depicts one example of a method of measuring a load current of a bridge circuit according to some embodiments.

### DETAILED DESCRIPTION

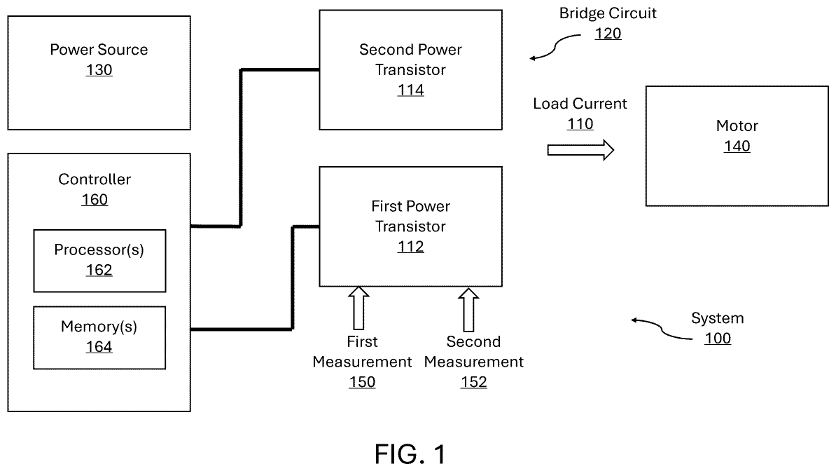

FIG. 1 is a block diagram of a system 100 configured to control an electric motor 140 according to some embodiments. System 100 includes a controller 160 configured to control power transistors of a bridge circuit 120 to supply energy from a power source 130 to the motor 140. The bridge circuit 120 includes a high side including at least one High Side (HS) power transistor and a low side including at least one Low Side (LS) power transistor. The power transistors are operable as a pair corresponding to a phase of the motor 140. In some example, the electric motor 140 may be a two phase electric motor, and the bridge circuit 120 may be configured as an H-bridge circuit with a high side that includes a pair of HS transistors and a low side that includes pair of LS transistors. The high and low side power transistors of the bridge circuit 120 are switched synchronously to one another to alternately deliver energy with a first polarity to drive a first phase of the two phase motor, and with a second, opposite, polarity (i.e., reverse motor control) to a second phase of the two phase motor. In other examples, the bridge circuit 120 is configured with a high side and a low side that each include three pairs of power transistors to deliver energy to each of three phases of a three-phase electric motor 140, with each phase 120 degrees out of phase relative to the other two phases.

Motor 140 may be a direct current (DC) motor such as a brushless DC (BLDC) motor, a stepper motor, an AC motor, or any other type of motor that may be widely used in applications, e.g., to drive fans, open and close windows, open and close a sunroof, adjust seat positioning, operate pumps, control flaps, as well as many other operations in vehicles. An electric motor in the abstract regard is performing a transformation of electric energy into mechanical energy. This is achieved by the generation of a dynamic magnetic field which changes the position of the rotor of such a motor. The dynamic magnetic field can be in the stator or in the rotor of the motor 140. The motor 140 can be controlled to run with a constant speed, a constant torque or to be driven in a defined position.

The speed of an electric motor 140 may be dependent on the voltage applied, motor-specific electric, magnetic and mechanical characteristics and the load torque. The drive of the motor 140 implemented by power transistors which may be semiconductor devices like MOSFETs, bipolar transistors or IGBTs. In other examples, the power transistors may be implemented with other materials, such as high band gap materials like Gallium Nitride (GaN) and/or Silicon Carbide (SIC). The power transistors may be applied to the motor 140 using a bridge circuit 120 as shown in the example of FIG. 1. The bridge circuit 120 may be a half-bridge, a full bridge, an h-bridge, or H-bridge. In another example, such as when the motor 140 is a stepper motor, the bridge circuit 120 may include four half bridge circuits. The bridge circuit 120 controls the operation of the motor 140 by changing the connection to the supply, the motor supply voltage and current (statically or dynamically) and the freewheeling to discharge the motor coil. The power transistors of the bridge circuit 120 can be either put into a constant state (i.e., turned on to conduct current, or turned off so as to not conduct current) or can be driven with a pulse-width modulation signals that allow a very accurate control of the on- and off-times of the power transistors. This can be used to implement a control loop.

In the example of FIG. 1, the controller 160 is coupled to control the bridge circuit 120 to supply energy, i.e., a load current I_{L}, to the motor 140. The controller 160 may include one or more processor(s) 162 that may be a microprocessor or any other type of processing component to execute instructions stored in one or more memory component(s) 164 to generate the control signals. In some examples, the controller 160 is implemented as a microcontroller that includes the processor(s) 162 and the memory component(s) 164 housed together in a semiconductor package. In other examples, the one or more processors 162 and/or the one or more memory component(s) 164 may be implemented as discrete components or otherwise arranged to implement the functions described herein.

The controller 160 may be coupled to deliver control signals to one or more driver circuit(s) (not shown in FIG. 1) that receive the control signal and generate amplified driver signals with sufficient current to turn on and turn off the power transistors of the bridge circuit 120 at fast speeds. The controller 160 causes the power transistors of the bridge circuit 120 to turn on and off to control the level of load current I_{L} delivered to the motor 140.

In some examples, the controller 160 controls the bridge circuit 120 to drive the motor 140 based on feedback. Such feedback may include sensor information such as angular speed, torque, and/or a rotational position of a rotor in relation to a stator. In some examples, a load current I_{L} 110 supplied to the motor may be measured as feedback. In some examples, a load current I_{L} 110 supplied to the motor 140 may be proportional to a torque generated by the motor 140.

In traditional motor control systems, a load current supplied to a motor may be determined by measuring a voltage across one or more dedicated shunt resistors with a known resistance that is coupled in series with a bridge circuit. In some examples, because the shunt resistor sees the same magnitude of current as the motor, the shunt may dissipate a significant amount of energy and impact the efficiency of the traditional motor control system. For example, such a resistor may dissipate I²R power, where I is the current and R is the resistance of the shunt. In some example, using a shunt to measure a load current may in a traditional motor control system may cause further power loss while allowing time for the shunt to warm up. In some examples, motor currents may be in the range of amps to hundreds of amps. Accordingly, the size, which directly correlates to resistance, of a shunt may be chosen as small as possible to reduce the impact on efficiency. In some examples, too small a shunt (i.e., to low a resistance) may impact a measurability and/or resolution of measurements across the terminals of the shunt.

System 100 depicted in FIG. 1 is uniquely configured to implement shuntless measurement of a load current I_{L}. Instead of implementing a dedicated resistor component as a shunt as described above with respect to traditional motor control systems, system 100 is configured to determine the load current I_{L} based on measurements performed on a power transistor 112 of the bridge circuit 120. For example, the controller 160 may perform a first measurement 150 of the power transistor 112 to determine a temperature of the power transistor 112, for example by detecting a body voltage V_{B} of the power transistor 114. The controller 160 may use the determined temperature to estimate an R_{DSON} value of the power transistor 112. The controller 160 may also perform a second measurement 152 of the power transistor 112, to determine a drain voltage V_{D} of the power transistor 112.

The bridge circuit 120 may be operable in an ON phase in which a load current I_{L} is actively supplied to operate the motor 240 (i.e., the bridge circuit 120 couples the motor 140 such that a current flows through the motor 240 from a power supply to ground), and a freewheeling phase in which a freewheeling current flows through a body diode of the power transistor 112. In some examples, the controller 160 performs the first measurement 150 and the second measurement 152 during the freewheeling phase. The freewheeling current may flow, in some examples, from a source to a drain of the power transistor 112. In some examples, the power transistor is a first power transistor 112 of the bridge circuit 120 as shown in the FIG. 1 example, and the freewheeling phase is defined based on the switching operation of a second power transistor 114 of the bridge circuit 120. In some examples, the freewheeling phase is initiated by the second power transistor 114 turning off, which ends an on phase of the bridge circuit 120. In some examples, the freewheeling phase ends when the second power transistor 114 is turned on to begin an on phase of the bridge circuit 120.

In some examples, the freewheeling phase includes a passive part and an active part. The passive part may be referred to as a deadtime of the power transistor 112 in which both the first power transistor 112 and the second power transistor 114 are turned off to avoid cross-conduction. In some examples, the passive part of the freewheeling phase is initiated by the second power transistor 114 switching off. In some examples, the passive part of the freewheeling phase ends, and the active part of the freewheeling phase begins, when the first power transistor 112 is turned on. In some examples, the active part of the freewheeling phase, in which the first power transistor 112 is turned on, may be referred to as an inductor discharge phase. In some examples, the active part of the freewheeling phase ends when the first power transistor 112 is turned off. In some examples, the passive part of the freewheeling phase is before the active part of the freewheeling phase in a switching cycle, and the controller 160 performs the first measurement 150 before the second measurement 152 during the freewheeling phase of the switching cycle. In other examples, the passive part of the freewheeling phase is after the active part of the freewheeling phase in the switching cycle, and the controller 160 performs the first measurement 150 after the second measurement 152 during the freewheeling phase of the switching cycle.

In some examples, the controller 160 is operable to perform the first measurement 150 and the second measurement 152 during a low side freewheeling phase in which a freewheeling current flows through a low side of the bridge circuit 120. According to such examples, the first power transistor 112 is a low side transistor of the bridge circuit 120, and the second power transistor 114 is a high side transistor of the bridge circuit 120, and the freewheeling current flows through a first low side transistor and a second low side transistor of the bridge circuit 120.

In other examples, the controller 160 is operable to perform the first measurement 150 and the second measurement 152 as described herein during a high side freewheeling phase in which a freewheeling current flows through a high side of the bridge circuit 120. According to such examples, the first power transistor 112 is a high side transistor of the bridge circuit 120, the second power transistor 114 is a low side transistor of the bridge circuit 120, and the freewheeling current flows through a first high side transistor and a second high side transistor of the bridge circuit 120.

The controller 160 may use the first measurement 150 and the second measurement 152 to determine a load current I_{L} of the power transistor 112. As mentioned above, the controller 160 may use the first measurement 150 as an indication of a junction temperature of the power transistor 112. As shown in FIG. 1, the controller 160 may include one or more processor(s) 162 to access one or more stored data structures, such as a lookup table, stored in one or more memory component(s) 164 accessible to the one or more processors 162. Such stored data may map body voltage V_{B} measurements, which reflect a temperature of the power transistor 112, to R_{DSON} values for the power transistor 112. The R_{DSON} values represent resistances of the power transistor 112 when the power transistor 112 is in an on state and conducting current. The controller 160 may access the stored data to map the first measurement 150 (the body voltage V_{B}) to an R_{DSON} value for the power transistor 112.

The controller 160 may use the R_{DSON} value (determined based on the first measurement 150) and the second measurement 152 (the detected drain voltage V_{D}) to determine the load current I_{L}. For example, the load current I_{L} may be determined based on the R_{DSON} value and the drain voltage V_{D} according equation (1) below:

$${I}_{L} = {V}_{D} / {R}_{DSON} \qquad ( 1 )$$

Where I_{L} is the load current, V_{D} is the detected drain voltage of the first power transistor 112 (the second measurement 152), and R_{DSON} is an on-resistance of the first power transistor 112 (determined based on the first measurement 150).

In some examples, the controller 160 may determine a load current I_{L} based on a measurements 150, 152 taken during a single switching cycle of the bridge circuit 120, determine a value of the load current I_{L} based on the first and second measurements according to equation (1) as described above, and use the determined value as feedback to control the bridge circuit 120.

In some examples, the controller 160 may execute an iterative process to determine the load current I_{L} based on performing the first and second measurements 150, 152 during the freewheeling phase of the bridge circuit 120. In particular, the controller 160 may determine an estimate of the junction temperature associated with the first power transistor 112 based on an assumption of a current level and the first measurement 150 (the body voltage V_{B} of the first power transistor 112), and determine an R_{DSON} value associated with first power transistor 112 based on the estimated junction temperature. The controller 160 may determine a new assumption of the current level based on the determined R_{DSON} value and the second measurement 152 (the drain voltage V_{D} of the first power transistor 112), and the controller 160 may iterate between determining a new estimate of the load current I_{L}, determining a new value of R_{DSON} based on the first measurement 150, and determining the load current I_{L} based on the new value of R_{DSON} and the second measurement 152 (the drain voltage V_{D} of the first power transistor 112). In some examples, the controller 160 may perform such iterations for N switching cycles, wherein N is a positive integer greater than 2. After N iterations, the controller 160 may determine an accurate estimation of the load current I_{L}.

As mentioned above, the motor 140 depicted in FIG. 1 may be two phase motor or may be a three phase motor configured to be driven as three separate phases separated from one another by 120 degrees. According to examples where the motor is a three phase motor, the bridge circuit 120 includes a high side with three high side power transistors HS1, HS2, and HS3, and a low side with three low side power transistors LS1, LS2, LS3. According to these examples, the first and second measurements 150, 152 may be performed on any one of the high side power transistors HS1, HS2, HS3 or any one of the low side power transistors LS1, LS2, LS3 of the bridge circuit 120 as the first power transistor 112 shown in FIG. 1. In still other examples not depicted herein, a bridge circuit 120 may include any number of high side and low side transistors, and the controller may perform the first and second measurements 150, 152 during a freewheeling phase in which a freewheeling current flows through the body diode of the transistor to be measured (the first transistor 112 depicted in FIG. 1).

In some examples, the controller 160 may perform the first and second measurements 150, 152 on the first power transistor 112 during a freewheeling phase of a three phase bridge circuit. In some examples, the freewheeling phase is high side freewheeling phase where a freewheeling current flows through one or more of the high side power transistors HS1, HS2, and HS3. According to these examples, the second power transistor 114 is at least one of the low side power transistors LS1, LS2, LS3. In some such examples, the controller 160 performs the first and second measurement 150, 152 during a freewheeling phase in which each of the low side power transistors LS1, LS2, LS3 is turned off to isolate the high side power transistors HS1, HS2, and HS3 from a ground reference such that a freewheeling current flows through the high side power transistors HS1, HS2, and HS3.

In some examples, the freewheeling current is a low side freewheeling current flowing through the low side transistors LS1, LS2, LS3. According to these examples, the second power transistor 114 is at least one of the high side transistors HS1, HS2, and HS3. In some such examples, the controller 160 performs the first and second measurement 150, 152 during a freewheeling phase in which each of the high side power transistors HS1, HS2, and HS3 is turned off to isolate the low side power transistors LS1, LS2, LS3 from a power source 130 such that a freewheeling current flows through the low side power transistors LS1, LS2, LS3.

In some examples, the controller 160 may perform the first and second measurements 150,152 during a time period in which most, or all, of a freewheeling current passes through the power transistor 112 to be measured. For example, the controller 160 may perform the first and second measurements 150, 152 on a low or high side transistor associated with a phase of the three phase motor with a load current of a first polarity (i.e., positive or negative) when the load currents associated with the other two phases of the three phase motor have a second, opposite polarity (i.e., negative or positive). In some examples, the controller 160 may perform the first and second measurements 150, 152 on a low or high side transistor associated with a phase of the three phase motor when load currents associated with the other two phases cross one another.

In some examples, system 100 may be uniquely configured to determine a load current I_{L} 110 by performing the first and second measurements 150, 152 on one power transistor (the power transistor 112) of the bridge circuit 120. In some examples, performing the first and second measurements 150, 152 on one power transistor of the bridge circuit 120 may enable shuntless measurement of the load current I_{L}, that is relatively simple in comparison to prior techniques. In addition, system 100 is configured such that controller 160 performs the first and second measurements 150, 152 during a freewheeling phase (a low side and/or a high side freewheeling phase) of the bridge circuit 120. In some examples, performing the first and second measurements during a freewheeling phase may enable the first and second measurements 150, 152 to be performed relatively close to one another (e.g., within less than 100 microseconds, meaning the second measurement 152 is performed less than 100 microseconds before or after the first measurement 150), which may enable the load current I_{L} to be determined with a high level of accuracy. In some examples, the first and second measurements 150, 160 may be performed closer to one another, for example the first and second measurement 150, 160 may be performed within less than 50 microseconds, within less than 20 microseconds, or within less than 10 or less than 5 microseconds.

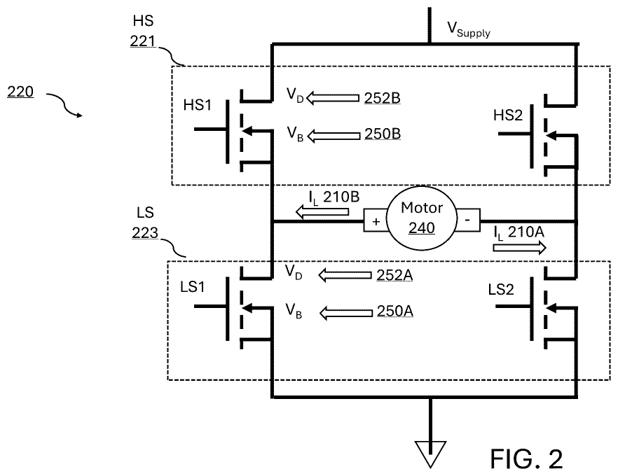

FIG. 2 is a circuit diagram that depicts a bridge circuit 220 according to some embodiments. The bridge circuit 220 corresponds to one example of a bridge circuit 120 that is controllable by a controller 160 to supply energy in the form of a load current I_{L} to drive a motor 240. In the example, of FIG. 2, the bridge circuit 220 is configured as an H-bridge circuit with a high side 221 that includes a first high side transistor HS1 and a second high side transistor HS2. Both the first high side transistor HS1 and the second high side transistor HS2 include a source terminal coupled to a power supply V_{S}. The first high side transistor HS1 includes a drain terminal coupled to a positive terminal of the motor 240. The second high side transistor HS2 includes a drain terminal coupled to a negative terminal of the motor 240.

In the example of FIG. 2, the bridge circuit 220 further includes a low side 223 that includes a low high side transistor LS1 and a second low side transistor LS2. Both the first low side transistor LS1 and the second low side transistor LS2 include a source terminal coupled to a ground reference. The first low side transistor LS1 includes a drain terminal coupled to a positive terminal of the motor 240, which is coupled to the source terminal of the first high side transistor HS1. The second low side transistor LS2 includes a drain terminal coupled to a negative terminal of the motor 240, which is coupled to the source terminal of the second high side transistor HS2.

In the example of FIG. 2, the transistors HS1, HS2, LS1 and LS2 are switchable between an on, or conducting state, and an off, or non-conducting state to control the load current I_{L} supplied to the motor 240. The motor 240 in the FIG. 2 example is a two phase motor with stator windings configured to generate two magnetic fields 90 degrees apart to drive one or more corresponding rotor(s). As described above with respect to FIG. 1, a controller 160 may be configured to perform a first measurement 150 to determine a temperature associated with a power transistor of the bridge circuit 220, and perform a second measurement 152 to determine a drain voltage of the power transistor, during a freewheeling phase of the bridge circuit 220.

In some examples, the freewheeling phase is a low side freewheeling phase in which a freewheeling current flows through the low side 223 (i.e., the low side transistors LS1 and LS2) of the bridge circuit 220. According to these examples, the first power transistor 112 depicted in FIG. 1 corresponds to one of the low side transistors LS1, LS2 of the bridge circuit 220, specifically the first low side transistor LS1 in the FIG. 2 example. As shown in FIG. 2, the controller 160 performs the first measurement 250A by detecting a body voltage V_{B} of the first low side transistor LS1, and performs the second measurement 252A by detecting a drain voltage V_{D} of the first low side transistor LS1. According to these examples, the second power transistor 114 depicted in FIG. 1 corresponds to one of more of the high side transistors HS1, HS2 of the bridge circuit which is turned off to decouple the low side 223 from the power source V_{S} to initiate the low side freewheeling phase, specifically the first high side transistor HS of the bridge circuit 220 in the FIG. 2 example. The second high side transistor HS2 may also be turned off during the high side freewheeling phase.

In some examples, the freewheeling phase is a high side freewheeling phase in which a freewheeling current flows through the high side 221 (i.e., the high side transistors HS1 and HS2) of the bridge circuit 220. According to these examples, the first power transistor 112 depicted in FIG. 1 corresponds to the one of the high side transistors HS1, HS2 of the bridge circuit 220, specifically the first high side transistor HS1 in the FIG. 2 example. According to this example, controller 160 performs the first measurement 250B by detecting a body voltage V_{B} of the first high side transistor HS1, and performs the second measurement 252A by detecting a drain voltage V_{D} of the first high side transistor HS1. According to these examples, the second power transistor 114 depicted in FIG. 1 corresponds to the first low side transistor LS1 of the bridge circuit 220, which is turned off to initiate the high side freewheeling phase. The second low side transistor LS2 may also be turned off during the high side freewheeling phase).

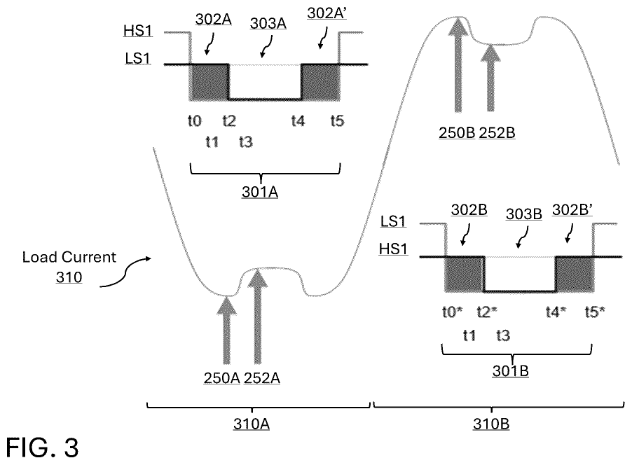

FIG. 3 is a timing diagram that depicts operation of a controller to control a bridge circuit to supply energy to a motor and measure a load current 310 according to some embodiments. The example of FIG. 3 may represent operation of a controller 160 as shown in FIG. 1 to control power switches of a bridge circuit 220 as shown in the example of FIG. 2. The left side of FIG. 3 shows first and second measurements 250A, 252A performed during a low side freewheeling phase 301A of a switching cycle 305A of the bridge circuit 220, when the load current 310 flows in a first direction. The right side of FIG. 3 shows first and second measurements 250B, 252B performed during a high side freewheeling phase 301B of a switching cycle 305B of the bridge circuit 220, when the load current 310 flows in a second direction different than the first direction.

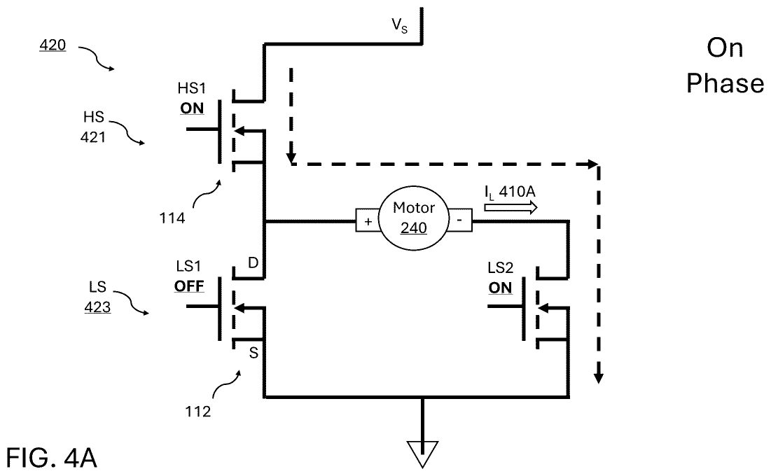

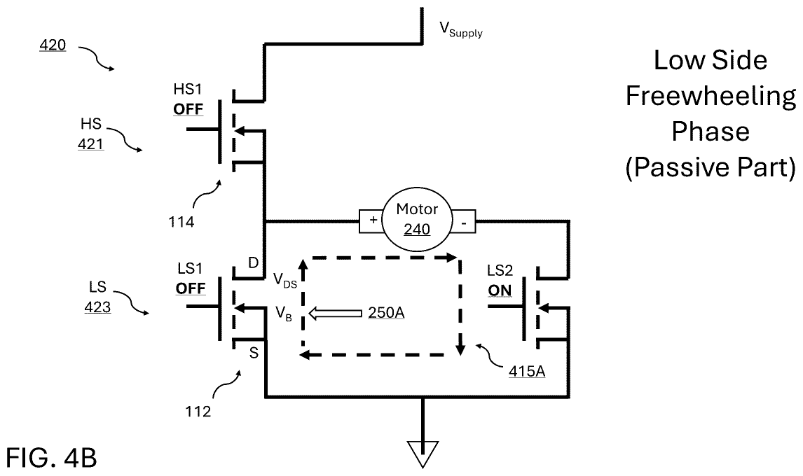

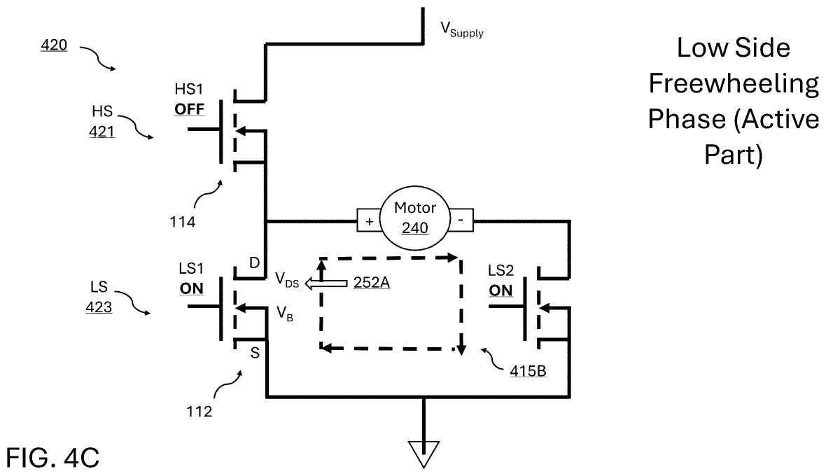

FIGS. 4A-4C are circuit diagrams that depict operation of a bridge circuit 420 in respective phases of a low side switching cycle 305A of the bridge circuit 420. The bridge circuit 420 depicted in FIGS. 4A-4C may correspond to the bridge circuit 220 depicted in FIG. 2 and includes a high side 421 and a low side 423, with the second high side switch HS2 turned off such that current does not flow through the second high side switch HS2. In other examples, the bridge circuit 420 depicted in FIG. 4A-4C corresponds to an h-bridge circuit configured to drive the motor 240 only in one direction that does not include a second high side switch HS2.

Referring to the timing diagram of FIG. 3, prior to operating in the depicted low side freewheeling phase 301A, the bridge circuit may be operated in an on, (i.e., active), phase. FIG. 4A depicts one example of the bridge circuit 420 operated in an on phase. In the on phase, the first high side transistor HS1 and second low side transistor LS2 are turned on such that a load current 410 flows from a positive terminal to a negative terminal of the motor 240, from the power supply V_{S} to the ground reference. As shown in FIG. 4A, in the on phase, the first low side transistor LS1 is turned off, which decouples the positive terminal of the motor 240 from the ground reference. In the example of FIGS. 4A-4C, the first low side transistor LS1 corresponds to the first power transistor 112 of FIG. 1, and the first high side transistor HS1 corresponds to the second power transistor 114 of FIG. 1.

Referring to the timing diagram of FIG. 3, at a time t0, the low side freewheeling phase 301A is initiated when the first high side transistor HS1 is turned off, which causes a freewheeling current 415A, 415B to flow through the low side 423 of the bridge circuit 420. As also shown in FIG. 3, at the time t5, the low side freewheeling phase 301A ends when the first high side transistor HS1 is turned on, commencing a subsequent on phase as shown in the FIG. 4A example. As shown in FIG. 3, a controller 160 performs a first measurement 250A (e.g., to detect a body voltage V_{B}) and a second measurement 252A (e.g., to detect a drain voltage V_{D}) during the low side freewheeling phase 301A, to determine a load current I_{L} of the motor 240.

As shown in FIG. 3, the low side freewheeling phase 301A includes one or more passive part(s) 302A/302A′ and an active part 303A. As shown in FIG. 3, the passive part 302A corresponds to the time period between the time t0 when the first high side transistor HS1 is turned off, and the time t2, when the first low side transistor LS1 is turned on. As shown in FIG. 3, the active part 303A corresponds to the time period between the time t2 when the first low side transistor LS1 is turned on, and the time t4 when the first low side transistor LS1 is turned off. As shown in FIG. 3, the passive part 302A′ is defined as the time period between the time t4 when the first low side transistor LS1 is turned off at time t4, and the time t5 when the first high side transistor HS1 is turned on, ending the low side freewheeling phase 301A.

Referring now to the circuit diagram of FIG. 4B, in the passive part(s) 302A, 302A′ of the low side freewheeling phase 301A, the first high side switch HS1 is turned off, which decouples the power supply V_{S} from the positive terminal of the motor 240. As shown in FIG. 4B, in the passive part(s) 302A, 302A′ of the low side freewheeling phase 301A, the first low side transistor LS1 is turned off, and the second low side transistor LS2 is turned on. As shown in FIG. 4B, in the passive part(s) 302A, 302A′ of the low side freewheeling phase 301A, a freewheeling current 415A flows through the low side 423 of the bridge circuit 420 from the positive to the negative terminal of the motor 240, from the drain to the source of the second low side transistor LS2, and through the body diode of the first low side transistor LS1. As shown in FIG. 4B and FIG. 3, the controller 160 may perform a first measurement 250A at a time t1 that is during the passive part(s) 302A, 302A′ of the low side freewheeling phase 301A, for example to measure a body voltage V_{B} of the first power transistor 112, which the controller 160 may use to determine a temperature of the first low side transistor LS1 and/or an R_{DSON} value for the first low side transistor LS1.

Referring now to the circuit diagram of FIG. 4C, in the active part 303A of the low side freewheeling phase 301A, the first high side transistor HS1 is turned off, the second low side transistor LS2 is turned on, and the first low side transistor LS1 is turned on. As shown in FIG. 4C, in the active part 303A of the low side freewheeling phase 301A, a freewheeling current 415B flows through the low side 423 of the bridge circuit 420 from the positive to the negative terminal of the motor 240, from the drain to the source of the second low side transistor LS2, from the source to the drain of the first low side transistor LS1, and through the body diode of the first low side transistor LS1. As shown in FIG. 4C and in FIG. 3, the controller 160 may perform a second measurement 252A during the active part 303A of the low side freewheeling phase 301A, for example to determine a drain voltage V_{D} of the first low side transistor LS1.

In some examples, the first measurement 250A may be performed during the passive part 302A, before the second measurement 252A is performed in the active part 303A as shown in the FIG. 3 example. In other examples not depicted, the first measurement 250A may be performed during the passive part 302A′, after the second measurement 252A is performed. Regardless, in some examples, both the first measurement 250A and the second measurement 252A are performed within a short time of one another, for example during the same switching cycle 305A of the bridge circuit 220.

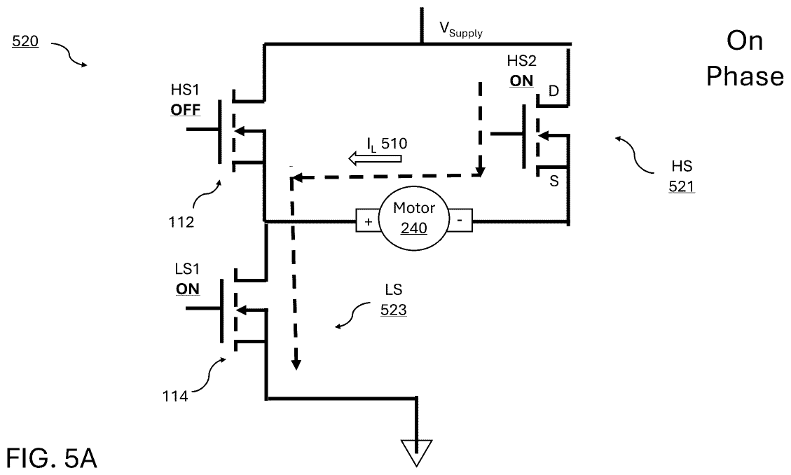

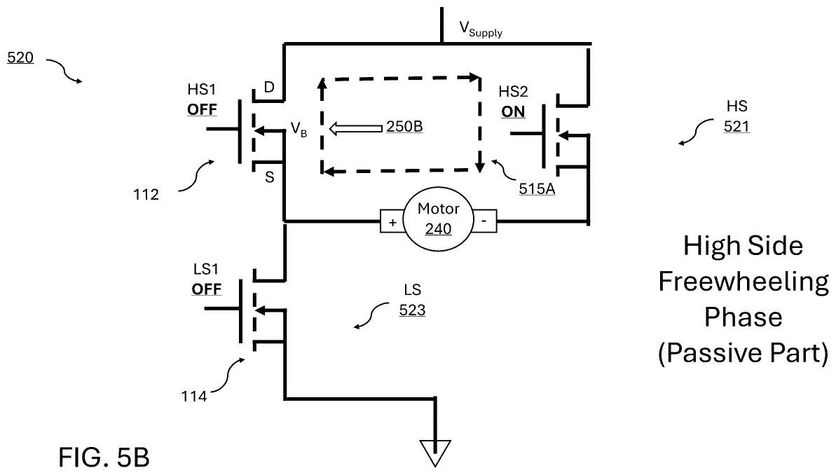

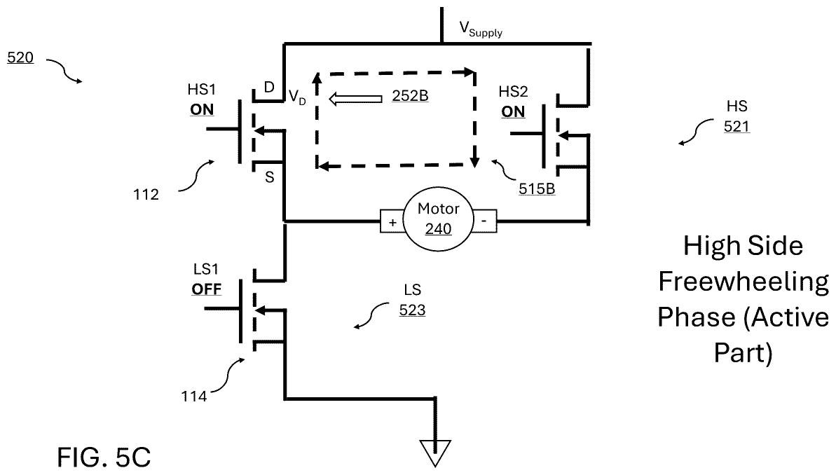

As mentioned above, the right side of FIG. 3 shows first and second measurements 250B, 252B performed during a high side freewheeling phase 301B of a switching cycle 305B of the bridge circuit 220. FIGS. 5A-5C are circuit diagrams that depict operation of a bridge circuit 520 in respective phases of a high side switching cycle 305B of the bridge circuit 520. The bridge circuit 520 depicted in FIGS. 5A-5C may correspond to the bridge circuit 220 depicted in FIG. 2 and includes a high side 521 and a low side 523, with the second low side switch LS2 turned off such that current does not flow through the second low side switch LS2. In other examples, the bridge circuit 520 depicted in FIG. 5A-5C corresponds to an h-bridge circuit configured to drive the motor 240 only in one direction that does not include a second low side switch LS2.

Referring to the timing diagram of FIG. 3, prior to operating in the depicted high side freewheeling phase 301B, the bridge circuit may be operated in an on, (i.e., active), phase. FIG. 5A depicts one example of the bridge circuit 520 operated in an on phase. In the on phase, the second high side transistor HS2 and the first low side transistor LS1 are turned on such that a load current I_{L} 510 current flows from a negative terminal to a positive terminal of the motor 240, from the power supply V_{S} to the ground reference. As shown in FIG. 5A, in the on phase, the second high side transistor HS1 is turned off, which decouples the positive terminal of the motor 240 from the power supply V_{S}. As shown in FIGS. 5A-5C, the first high side transistor HS1 corresponds to the first power transistor 112 of FIG. 1, and the first low side transistor LS1 corresponds to the second power transistor 114 of FIG. 1.

Referring to the timing diagram of FIG. 3, at a time t0*, the high side freewheeling phase 301B is initiated when the first low side transistor LS1 is turned off, which causes a freewheeling current 515A, 515B to flow through the high side 521 of the bridge circuit 520. As also shown in FIG. 3, at the time t4*, the high side freewheeling phase 301B ends when the first low side transistor LS1 is turned on, commencing a subsequent on phase as shown in the FIG. 5A example. As shown in FIG. 3, a controller 160 performs a first measurement 250B and a second measurement 252B during the high side freewheeling phase 301B, to determine a load current I_{L} 510 of the motor 240.

As shown in FIG. 3, the high side freewheeling phase 301B includes one or more passive part(s) 302B/302B′ and an active part 303B. As shown in FIG. 3, the passive part 302B corresponds to the time period between the time t0* when the first low side transistor LS1 is turned off, and the time t2*, when the first high side transistor HS1 is turned on. As shown in FIG. 3, the active part 303B corresponds to the time period between the time t2* when the first high side transistor HS1 is turned on, and the time t4* when the first high side transistor HS1 is turned off. As shown in FIG. 3, the passive part 302B′ is defined as the time period between the time t4* when the first high side transistor HS1 is turned off at time t4*, and the time t5* when the first low side transistor LS1 is turned on, ending the high side freewheeling phase 301B.

Referring now to the circuit diagram of FIG. 5B, in the passive part(s) 302B, 302B′ of the high side freewheeling phase 301B, the first low side transistor LS1 is turned off, which decouples the positive terminal of the motor 240 from the ground reference. As shown in FIG. 5B, in the passive part(s) 302B, 302B′ of the high side freewheeling phase 301B, the first high side transistor HS1 is turned off, and the second high side transistor HS2 is turned on. As shown in FIG. 5B, in the passive part(s) 302B, 302B′ of the high side freewheeling phase 301B, a freewheeling current 515A flows through the high side 521 of the bridge circuit 520 from the drain to the source of the second high side transistor HS2, from the negative to the positive terminal of the motor 240, and through the body diode of the first high side transistor HS1. As shown in FIG. 5B and in FIG. 3, the controller 160 may perform a first measurement 250B at a time t1* that is during the passive part(s) 302B, 302B′ of the high side freewheeling phase 301B, for example to measure a body voltage V_{B} of the first high side transistor HS1, to determine a temperature and/or R_{DSON} value of the first high side transistor HS1.

Referring now to the circuit diagram of FIG. 5C, in the active part 303B of the high side freewheeling phase 301B, the first high side transistor HS1 is turned on, the second high side transistor HS2 is turned on, and the first low side transistor LS1 is turned off. As shown in FIG. 5C, in the active part 303B of the high side freewheeling phase 301B, a freewheeling current 515B flows from the drain to the source of the second high side transistor HS2, from the negative to the positive terminal of the motor 240, from the source to the drain of the first high side transistor HS1 and through the body diode of the first high side transistor HS1. As shown in FIG. 4C and in FIG. 3, the controller 160 may perform a second measurement 252B during the active part 303B of the high side freewheeling phase 301B, for example to determine a drain voltage V_{D} of the first high side transistor HS1.

In some examples, the first measurement 250B may be performed during the passive part 302B, before the second measurement 252B is performed in the active part 303B as shown in the FIG. 3 example. In other examples not depicted, the first measurement 250B may be performed during the passive part 302B′, after the second measurement 252B is performed. Regardless, in some examples, both the first measurement 250B and the second measurement 252B are performed within a short time of one another, for example during the same switching cycle 305A of the bridge circuit 220.

As shown in the example of FIG. 3, a controller 160 as described herein may perform a first measurement 150 and a second measurement 152 during a freewheeling phase of the bridge circuit 220, which may be measurements 250A, 252A taken during a low side freewheeling phase 301A of the bridge circuit 220. In other examples, the first and second measurements 150, 152 may also, or instead include measurements 250B, 252B taken during a high side freewheeling phase 301B of the bridge circuit 220. In some examples, the controller may perform the respective first measurements 250A, 250B during a freewheeling phase of a different switching cycle 305A, 305B than the second measurements 252A, 252B. In other examples, as shown in the FIG. 3 diagram, the controller 160 may perform the respective first measurements 250A, 250B, during the same switching cycle as the second measurements 252A, 252B. In some examples, the controller 160 may perform the respective first measurements 250A, 250B close in time to the second measurements 252A, 252B. For example, the controller 160 may perform the second measurements 252A, 252B within 100 microseconds of performing the first measurements 250A, 250B. In some examples, the first and second measurements 150, 160 may be performed within less than 50 microseconds, within less than 20 microseconds, or within less than 10 or less than 5 microseconds.

In some examples, a controller 160 as described herein may perform the first measurement 250A and the second measurement 252A during a low side freewheeling phase 301A of a high side switching cycle, and perform the first measurement 250B and the second measurement 252B during a subsequent high side freewheeling phase 301B as shown in the FIG. 3 timing diagram, and use both measurements to determine the load current I_{L} 210A, 210B. In other examples, the controller 160 may perform only the first measurement 250A and the second measurement 252A during the low side freewheeling phases, and not perform the first measurement 250B and the second measurement 252B during a high side freewheeling phases 301B. Likewise, the controller may perform only the first measurement 250B and the second measurement 252B during the high side freewheeling phases, and not perform the first measurement 250A and the second measurement 252A during low side freewheeling phases 301A.

The examples shown in FIGS. 4A-4C and 5A-5C are provided for purposes of explanation and are intended to be non-limiting. One of ordinary skill in the art will recognize that the depicted bridge circuits 420 and 520 are symmetrical and may be operated opposite to the way described. For example, FIGS. 4A-4C depict a low side freewheeling phase that follows an on phase where the first high side transistor HS1 and second low side transistor LS2 operate as active transistors that create a current path from the power source V_{S} to the ground reference through the motor 240 (from the positive terminal to the negative terminal of the motor). According to these examples, the first low side transistor LS1 corresponds to the first power transistor 112 of FIG. 1, the first high side transistor HS1 corresponds to the second power transistor 114 of FIG. 1, and the first and second measurements 150, 152 are performed relative to the first low side transistor LS1. In other examples not depicted, a low side freewheeling phase follows an on phase where the second high side transistor HS2 and first low side transistor LS1 operate as active transistors that create a current path from the power source V_{S} to the ground reference through the motor 240 (from the negative terminal to the positive terminal of the motor). According to these examples, the second low side transistor LS2 corresponds to the first power transistor 112 of FIG. 1, the second high side transistor HS2 corresponds to the second power transistor 114 of FIG. 1, and the first and second measurement 150, 152 are performed relative to the second low side transistor LS2.

As another example, FIGS. 5A-5C depict a high side freewheeling phase that follows an on phase where the second high side transistor HS2 and first low side transistor LS1 operate as active transistors that create a current path from the power source V_{S} to the ground reference through the motor 240 (from the negative terminal to the positive terminal of the motor). According to these examples, the first high side transistor HS1 corresponds to the first power transistor 112 of FIG. 1, the first low side transistor LS1 corresponds to the second power transistor 114 of FIG. 1, and the first and second measurements 150, 152 are performed relative to the first high side transistor HS1. In other examples not depicted, a high side freewheeling phase follows an on phase where the first high side transistor HS1 and second low side transistor LS2 operate as active transistors that create a current path from the power source V_{S} to the ground reference through the motor 240 (from the positive terminal to the negative terminal of the motor). According to these examples, the second high side transistor HS2 corresponds to the first power transistor 112 of FIG. 1, the second low side transistor LS2 corresponds to the second power transistor 114 of FIG. 1, and the first and second measurement 150, 152 are performed relative to the second high side transistor HS2.

In some examples, the controller 160 may execute an iterative process to determine the load current I_{L} based on performing the first and second measurements during the freewheeling phase of the bridge circuit 220. In particular, the controller 160 may determine an estimate of the junction temperature associated with the first power transistor 112 based on an assumption of a current level and the first measurement 250A, 250B (the body voltage V_{B} of the first power transistor 112), and determine an R_{DSON} value associated with first power transistor 112 based on the determined estimate of junction temperature. The controller 160 may determine an assumption of the current level based on the determined R_{DSON} value and the second measurement 252A, 252B (the drain voltage V_{D} of the first power transistor 112). The controller 160 may iterate across multiple switching cycles between determining a new estimate of the load current I_{L}, determining a new value of R_{DSON} based on the first measurement 250A, 250B, and determining the load current I_{L} based on the second measurement 252A, 252B. In some examples, the controller 160 may perform such iterations for N switching cycles, wherein N is a positive integer greater than 2. After N iterations, the controller 160 may determine an accurate estimation of the load current I_{L}.

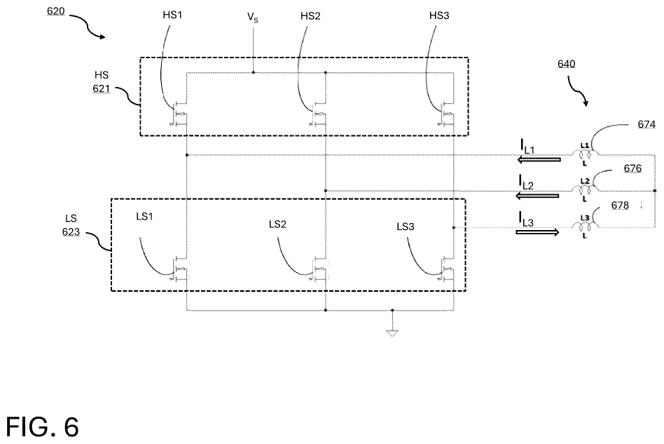

FIG. 6 is a circuit diagram showing one example of a three phase bridge circuit 620 that may be operated to determine a load current associated with at least one phase of the bridge circuit 620 according to some embodiments. The bridge circuit 620 corresponds to the bridge circuit 120 depicted in FIG. 1. In the example of FIG. 6, a three phase motor 640 is modeled by three inductors. A first inductor represents a first phase 674 of the motor 640, a second inductor represents a second phase 676 of the motor 640, and a third inductor represents a third phase 678 of the motor 640.

As shown in FIG. 6, the bridge circuit 620 includes a high side 621 and a low side 623. The high side 621 includes three high side power transistors H1, H2, and H3. The low side 623 includes three low side power transistors L1, L2, and L3 configured to be switched in synchronization with the three high side transistors H1, H2, and H3 to deliver a load current to each phase 674, 676, 678 of the motor 640. According to the example of FIG. 6, the first high side transistor HS1 and the first low side transistor LS1 are operated to supply a load current I_{L}1 to the first phase 676 of the motor. The second high side transistor H2 and the second low side transistor L2 are operable to supply a load current I_{L}2 to the second phase 678 of the motor. The third high side transistor H3 and the third low side transistor L3 are operable to supply a load current I_{L}3 to the second phase 678 of the motor.

Like the bridge circuit 120 depicted in FIG. 1, the controller 160 may be configured to perform first and second measurements 150, 152 on one or more of the high side transistors H1, H2, H3 and/or one or more of the low side transistors L1, L2, L3 during a freewheeling phase in which a freewheeling current flows through a body diode of the respective transistor.

For example, the freewheeling phase may be a low side freewheeling phase in which a freewheeling current flows through one or more of the low side transistors L1, L2, L3. According to these examples, the first power transistor 112 of FIG. 1 corresponds to the one or more low side transistors L1, L2, L3 to be measured. According to this example, the second power transistor 114 of FIG. 1 corresponds to one or more of the high side transistors H1, H2, H3 that are turned off to decouple the high side 621 from the low side 623 such that a freewheeling current flows through the one or more low side 623. A controller 160 may be configured to perform the first measurement 150, to detect a body voltage V_{B} of the transistor to be measured, during a passive part of the low side freewheeling phase. The controller 160 may be configured to perform the second measurement 152, to detect a drain voltage V_{D} of the transistor to be measured, during an active part of the low side freewheeling phase.

As another example, the freewheeling phase may be a high side freewheeling phase in which a freewheeling current flows through one or more of the high side transistors H1, H2, H3. According to these examples, the first power transistor 112 of FIG. 1 corresponds to the one or more high side transistors H1, H2, H3 to be measured. According to this example, the second power transistor 114 of FIG. 1 corresponds to one or more of low side transistors L1, L2, L3 that are turned off to decouple the low side 623 from the high side 621 such that a freewheeling current flows through the one or more high side transistors H1, H2, H3 to be measured. A controller 160 may be configured to perform the first measurement 150, to detect a body voltage V_{B} of the transistor to be measured, during a passive part of the high side freewheeling phase. The controller 160 may be configured to perform the second measurement 152, to detect a drain voltage V_{D} of the transistor to be measured, during an active part of the high side freewheeling phase.

In some examples, regardless of whether the bridge circuit is a three phase bridge circuit 620 as shown in FIG. 6, a two phase bridge circuit 220 as shown in FIG. 2, or any other type of bridge circuit including any number of high side and low side transistors the controller 160 may be configured to perform the first and second measurements on a particular power transistor based on a direction of current flow to the motor. For example, the controller 160 may perform the first and second measurements 150, 152 on the third low side transistor LS3 when the current I_{L}3 is flowing from the motor 640 to the bridge circuit 620, as shown in FIG. 6. In other examples not depicted in FIG. 6, the controller 160 may perform the first and second measurements 150, 152 on the third high side transistor HS3 when the current I_{L}3 is flowing in the opposite direction, from the bridge circuit 620 to the motor 640. In still other examples, the controller 160 may operate in the reverse, and perform the first and second measurements 150, 152 on the third high side transistor HS3 when the current is flowing from the motor 640 to the bridge circuit 620, and/or perform the first and second measurements 150, 152 on the third low side transistor LS3 when the current I_{L}3 is flowing in the opposite direction, from the bridge circuit 620 to the motor 640. The same principle may be applied to any of the three phases of the bridge circuit 620 depicted in FIG. 6, or any other bridge circuit not explicitly depicted and/or described herein that includes a plurality of high side and low side transistors.

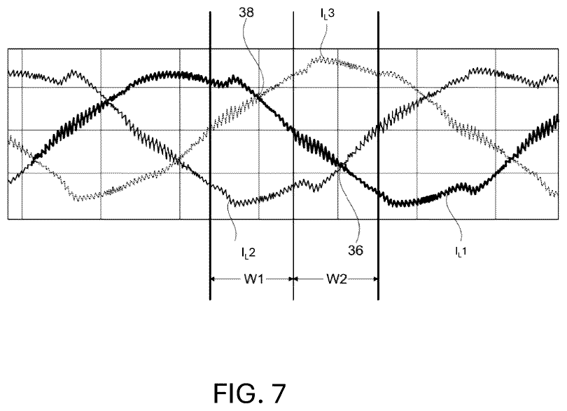

FIG. 7 is a graph that shows three different waveforms of current associated with three phases 674, 676, 678 of a three-phase electric motor. FIG. 7 depicts relative timing for controller 160 to perform a first measurement 150 and a second measurement 152 for a three phase bridge circuit 620 depicted in FIG. 6. In some examples, the controller 160 may perform the first measurement 150 and the second measurement 152 during a freewheeling phase of one or more of power transistors HS1, HS2, HS3, LS1, LS2, LS3. The example of FIG. 7 shows a first phase current signal I_{L}1 supplied to the first phase 674, a second phase current signal I_{L}2 supplied to the second phase 676, and a third phase current signal I_{L}3 supplied to the third phase 678. According to this disclosure, the controller 160 may perform the first measurement 150 (to detect a body voltage V_{B} of one of the power switches) and the second measurement 152 (to detect a drain voltage V_{D} of one of power switches) during a freewheeling phase in which a freewheeling current flows through the power transistor to be measured.

In some examples, the controller 160 may perform the first measurement 150 and the second measurement 152 at a point in time when it is known that all, or a majority of, a high side or a low side freewheeling current is flowing through that power transistor. For example, to measure the load current I_{L}3 of the third phase 678 depicted in FIG. 6, the controller 160 may perform the first measurement 150 and the second measurement 152 during a low side freewheeling phase 301A, i.e., at a point in time when most or all of the high side transistors HS1, HS2, and HS3 are turned off, which causes a freewheeling current to flow between the third low side transistor LS3 and the second low side transistor LS2, as well as a freewheeling current between the third low side transistor LS3 and the first low side transistor LS1. The controller 160 may perform the first measurement 250A during a passive part 302A, 302A′ of the freewheeling phase 301A, and perform the second measurement 252A during an active part 303A of the freewheeling phase 301A, as shown in the timing diagram of FIG. 3.

As another example, to measure the load current I_{L}3 of the third phase 678 depicted in FIG. 6, the controller 160 may perform the first measurement 250B and the second measurement 250B during a high side freewheeling phase 301B as shown in the example of FIG. 3, i.e., at a point in time when most or all of the low side transistors LS1, LS2, and LS3 are off, which causes a freewheeling current to flow between the third high side transistor HS3 and the second high side transistor HS2, as well as a freewheeling current to flow between the third high side transistor HS3 and the first high side transistor HS1. The controller 160 may perform the first measurement 250B during a passive part 302B, 302B′ of the high side freewheeling phase 301B, and perform the second measurement 252B during an active part 303B of the high side freewheeling phase 301B.

In some examples, a controller 160 may be configured to perform the first measurements 150, and second measurements 152 to determine a load current I_{L}1, I_{L}2, I_{L}3 for each respective phase 674, 676, 678 of the bridge circuit 620. Referring to FIG. 7, in some examples, the controller 160 may perform the first measurement 150 and the second measurement 152 at a point in time when it is known that all or most of a high side or low side freewheeling current is flowing through that power switch. For a high side transistor HS3 associated the third phase current I_{L}3, this point of time may occur during the window W2 in FIG. 7, when the third phase current I_{L}3 is positive and the phase currents I_{L}2 and I_{L}1 are negative. In some examples, the controller 160 may perform the first measurement 150 and the second measurement 152 for the LS3 power switch with the third phase current I_{L}3 at or near the point in time 36 when the phase currents I_{L}2 and I_{L}1 are at a crossing point.

Similarly, as another example referring to FIG. 7, the controller 160 may perform the first measurement 150 and the second measurement 152 associated with a second phase current I_{L}2, at a point in time when all or most of a freewheeling current is flowing through the second low side transistor LS2. This point in time may correspond to window W1, when the second phase current I_{L}2 is negative and the phase currents I_{L}3 and Iₗ1 are positive. In some examples, the controller 160 may perform the first measurement 150 and the second measurement 152 during a freewheeling phase associated with second phase current I_{L}2 at or near the point in time 38 when the phase currents I_{L}3 and I_{L}1 are at a crossing point.

In some examples, the controller 160 may execute an iterative process to determine the load currents I_{L}1, I_{L}2, and/or I_{L}3 based on performing the first and second measurements 150, 152 during the freewheeling phase of the bridge circuit 620. In particular, the controller 160 may determine an estimate of the junction temperature associated with a power circuit of the bridge circuit 620 based on an assumption of a current level and the first measurement 150 (the body voltage V_{B} of the power transistor), and determine an R_{DSON} value associated with the power transistor based on the determined estimate of junction temperature. The controller 160 may determine an assumption of the current level based on the determined R_{DSON} value and the second measurement 150 (the drain voltage V_{D} of the first power transistor). The controller 160 may iterate between determining a new estimate of the load current I_{L}, determining a new value of R_{DSON} based on the first measurement 150, and determining the load current I_{L} based on the second measurement 152. In some examples, the controller 160 may perform such iterations for N switching cycles, wherein N is a positive integer greater than 2. After N iterations, the controller 160 may determine an accurate estimation of the load current I_{L}1, I_{L}2, and/or I_{L}3.

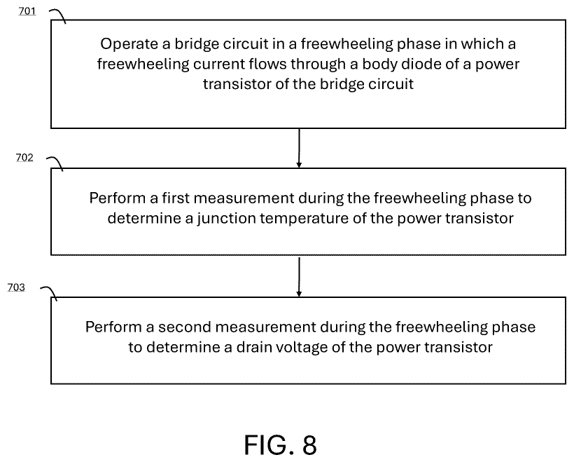

FIG. 8 is a flow diagram that depicts one example of a method of measuring a load current of a bridge circuit according to some embodiments. As shown in FIG. 8, at 801, the method includes operating a bridge circuit 120 in a freewheeling phase 301A, 301B in which a freewheeling current flows through a body diode of a power transistor 112 of the bridge circuit 120. As shown in FIG. 8, the method further includes, at 802, performing a first measurement 150 (e.g., to detect a body voltage V_{B} of the power transistor 112) during the freewheeling phase 301A, 301B to determine a junction temperature of the power transistor. As also shown in FIG. 8, the method further includes, at 803, performing a second measurement 152 during the freewheeling phase 301A, 301B to determine a drain voltage of the power transistor 112.

In some examples, the method further includes performing the first measurement 150 during a passive part, 302A, 302A′, 302B, 302B′ of the freewheeling phase. In some examples, the method further includes performing the second measurement 152 during an active part 302A, 302B of the freewheeling phase 301A, 301B.

In some examples, the power transistor is a first power transistor 112 of the bridge circuit 120, and the method further includes performing the first measurement 150 after a second power transistor 114 of the bridge circuit 120 is turned off and before switching on the first power transistor 112. In some examples, the method further includes performing the second measurement 152 after switching on the first power transistor 112 and before switching off the first power transistor 112. In some examples, the freewheeling phase is a low side freewheeling phase 301A in which the freewheeling current 415A flows through a low side of the bridge circuit 120, the first power transistor is a low side transistor of the bridge circuit 120, and the second power transistor is a high side transistor of the bridge circuit 120. In some examples the freewheeling phase is a high side freewheeling phase 301B in which the freewheeling current 415B flows through a high side 221 of the bridge circuit 120, the first power transistor 112 is a high side transistor of the bridge circuit 120, and the second power transistor 114 is a low side transistor of the bridge circuit 120.

In some examples, the method further includes performing the second measurement less than 10 microseconds within (i.e., before or after) performing the first measurement. In some examples, the method further includes performing the first measurement and the second measurement during the freewheeling phase of a single switching cycle of the bridge circuit. In some examples, performing the first measurement 150 includes detecting a voltage drop across drain and source terminals of the power transistor 112, and performing the second measurement 152 includes measuring a voltage drop across a body diode of the power transistor 112.

In some examples, the method further includes using a junction temperature determined based on the first measurement 150 to determine an R_{DSON} of the power transistor 112, and using the second measurement 152 and the determined R_{DSON} of the power transistor 112 to determine a load current I_{L} of the bridge circuit 120.

### CLAUSES

Clause 1. A method, comprising: operating a bridge circuit in a freewheeling phase in which a freewheeling current flows through a body diode of a power transistor of the bridge circuit; performing a first measurement during the freewheeling phase to determine a junction temperature of the power transistor; and performing a second measurement during the freewheeling phase to determine a drain voltage of the power transistor.

Clause 2. The method of clause 1, further comprising: performing the first measurement during a passive part of the freewheeling phase; and performing the second measurement during an active part of the freewheeling phase.

Clause 3. The method of any of claims 1 and 2, wherein the power transistor is a first power transistor of the bridge circuit, and further comprising: performing the first measurement after a second power transistor of the bridge circuit is turned off and before turning on the first power transistor.

Clause 4. The method of clause 3, further comprising: performing the second measurement after switching on the first power transistor and before turning off the first power transistor.

Clause 5. The method of any of clauses 3 and 4, wherein the freewheeling phase is a low side freewheeling phase in which the freewheeling current flows through a low side of the bridge circuit, the first power transistor is a low side transistor of the bridge circuit, and the second power transistor is a high side transistor of the bridge circuit.

Clause 6. The method of any of clauses 3-5, wherein the freewheeling phase is a high side freewheeling phase in which the freewheeling current flows through a high side of the bridge circuit, the first power transistor is a high side transistor of the bridge circuit, and the second power transistor is a low side transistor of the bridge circuit.

Clause 7. The method of any of clauses 1-6, further comprising: performing the second measurement less than 10 microseconds within performing the first measurement.

Clause 8. The method of any of clauses 1-7, further comprising: performing the first measurement and the second measurement during the freewheeling phase of a single switching cycle of the bridge circuit.

Clause 9. The method of clause 8, further comprising one or more of: performing the first measurement before the second measurement during the switching cycle; and performing the second measurement before the first measurement during the switching cycle.

Clause 10. The method of any of clauses 1-9, wherein performing the first measurement comprises measuring a voltage drop across drain and source terminals of the power transistor, and the second measurement includes measuring a voltage drop across a body diode of the power transistor.

Clause 11. The method of any of clauses 1-10, further comprising: using the junction temperature determined based on the first measurement to determine an R_{DSON} of the power transistor; and using the second measurement and the determined R_{DSON} of the power transistor to determine a load current of the bridge circuit.

Clause 12. A controller configured to: control a bridge circuit in a freewheeling phase in which a freewheeling current flows through a body diode of a power transistor of the bridge circuit; perform a first measurement during the freewheeling phase to determine a junction temperature of the power transistor; and perform a second measurement during the freewheeling phase to determine a drain voltage of the power transistor.

Clause 13. The controller of clause 12, wherein the controller is configured to: perform the first measurement during a passive part of the freewheeling phase; and perform the second measurement during an active part of the freewheeling phase.

Clause 14. The controller of any of clauses 12 and 13, wherein the controller is configured to: perform the second measurement less than 10 microseconds within performing the first measurement.

Clause 15. The controller of any of clauses 12-14, wherein the controller is configured to: perform the first measurement and the second measurement during the freewheeling phase of a single switching cycle of the bridge circuit.

Clause 16. The controller of any of clauses 12-15, wherein the controller is configured to: use the junction temperature determined based on the first measurement to determine an R_{DSON} of the power transistor; and use the second measurement and the determined R_{DSON} of the power transistor to determine a load current of the bridge circuit.

Clause 17. A system, comprising: a motor; a bridge circuit that is controllable to supply energy to the motor; and a controller configured to: operate a bridge circuit in a freewheeling phase in which a freewheeling current flows through a body diode of a power transistor of the bridge circuit; perform a first measurement during the freewheeling phase to determine a junction temperature of the power transistor; and perform a second measurement during the freewheeling phase to determine a drain voltage of the power transistor.

Clause 18. The system of clause 17, wherein the controller is configured to: perform the first measurement during a passive part of the freewheeling phase; and perform the second measurement during an active part of the freewheeling phase.

Clause 19. The system of any of clauses 17 and 18, wherein the controller is configured to: perform the second measurement less than 10 microseconds within performing the first measurement.

Clause 20. The system of any of clauses 17-19, wherein the controller is configured to: perform the first measurement and the second measurement during the freewheeling phase of a single switching cycle of the bridge circuit.

Clause 21. The system of any of clauses 17-20, wherein the controller is configured to: use the junction temperature determined based on the first measurement to determine an R_{DSON} of the power transistor; and use the second measurement and the determined R_{DSON} of the power transistor to determine a load current of the bridge circuit.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A method, comprising:
operating a bridge circuit in a freewheeling phase in which a freewheeling current flows through a body diode of a power transistor of the bridge circuit;
performing a first measurement during the freewheeling phase to determine a junction temperature of the power transistor; and
performing a second measurement during the freewheeling phase to determine a drain voltage of the power transistor.

2. The method of claim 1, further comprising:
performing the first measurement during a passive part of the freewheeling phase; and
performing the second measurement during an active part of the freewheeling phase.

3. The method of claim 1, wherein the power transistor is a first power transistor of the bridge circuit, and further comprising:
performing the first measurement after a second power transistor of the bridge circuit is turned off and before turning on the first power transistor.

4. The method of claim 3, further comprising:
performing the second measurement after switching on the first power transistor and before turning off the first power transistor.

5. The method of claim 3, wherein the freewheeling phase is a low side freewheeling phase in which the freewheeling current flows through a low side of the bridge circuit, the first power transistor is a low side transistor of the bridge circuit, and the second power transistor is a high side transistor of the bridge circuit.

6. The method of claim 3, wherein the freewheeling phase is a high side freewheeling phase in which the freewheeling current flows through a high side of the bridge circuit, the first power transistor is a high side transistor of the bridge circuit, and the second power transistor is a low side transistor of the bridge circuit.

7. The method of claim 1, further comprising:
performing the second measurement less than 100 microseconds within performing the first measurement.

8. The method of claim 1, further comprising:
performing the first measurement and the second measurement during the freewheeling phase of a single switching cycle of the bridge circuit.

9. The method of claim 8, further comprising one or more of:
performing the first measurement before the second measurement during the switching cycle; and
performing the second measurement before the first measurement during the switching cycle.

10. The method of claim 1, wherein performing the first measurement comprises measuring a voltage drop across drain and source terminals of the power transistor, and the second measurement includes measuring a voltage drop across a body diode of the power transistor.

11. The method of claim 1, further comprising:
using the junction temperature determined based on the first measurement to determine an R_{DSON} of the power transistor; and
using the second measurement and the determined R_{DSON} of the power transistor to determine a load current of the bridge circuit.

12. A controller configured to:
control a bridge circuit in a freewheeling phase in which a freewheeling current flows through a body diode of a power transistor of the bridge circuit;
perform a first measurement during the freewheeling phase to determine a junction temperature of the power transistor; and
perform a second measurement during the freewheeling phase to determine a drain voltage of the power transistor.

13. The controller of claim 12, wherein the controller is configured to:
perform the first measurement during a passive part of the freewheeling phase; and
perform the second measurement during an active part of the freewheeling phase.

14. The controller of claim 12, wherein the controller is configured to:
perform the second measurement less than 10 microseconds within performing the first measurement.

15. The controller of claim 12, wherein the controller is configured to:
perform the first measurement and the second measurement during the freewheeling phase of a single switching cycle of the bridge circuit.

16. The controller of claim 12, wherein the controller is configured to:
use the junction temperature determined based on the first measurement to determine an R_{DSON} of the power transistor; and
use the second measurement and the determined R_{DSON} of the power transistor to determine a load current of the bridge circuit.

17. A system, comprising:
a motor;
a bridge circuit that is controllable to supply energy to the motor; and
a controller configured to:
operate a bridge circuit in a freewheeling phase in which a freewheeling current flows through a body diode of a power transistor of the bridge circuit;
perform a first measurement during the freewheeling phase to determine a junction temperature of the power transistor; and
perform a second measurement during the freewheeling phase to determine a drain voltage of the power transistor.

18. The system of claim 17, wherein the controller is configured to:
perform the first measurement during a passive part of the freewheeling phase; and
perform the second measurement during an active part of the freewheeling phase.

19. The system of claim 17, wherein the controller is configured to:
perform the first measurement and the second measurement during the freewheeling phase of a single switching cycle of the bridge circuit.

20. The system of claim 17, wherein the controller is configured to:
use the junction temperature determined based on the first measurement to determine an R_{DSON} of the power transistor; and
use the second measurement and the determined R_{DSON} of the power transistor to determine a load current of the bridge circuit.
